(19) United States
(12) Patent Application Publication
(10) Pub. No.: US 2026/0223521 A1
(43) Pub. Date: Jul. 30, 2026

(54) SOLAR CELL

(71) Applicant: TOYOTA JIDOSHA KABUSHIKI KAISHA, Toyota-shi (JP)

(72) Inventors: Kohei MATSUNOBU, Toyota-shi (JP); Kenichi OKUMURA, Gotemba-shi (JP); Mikihiro MORIYAMA, Toyota-shi (JP)

(73) Assignee: TOYOTA JIDOSHA KABUSHIKI KAISHA, Toyota-shi (JP)

(21) Appl. No.: 19/300,837

(22) Filed: Aug. 15, 2025

(30) Foreign Application Priority Data
Jan. 24, 2025 (JP) 2025-010434

(51) Int. Cl. H10K 30/87; H10K 30/40; H10K 30/88

(52) U.S. Cl. CPC H10K 30/87; H10K 30/40; H10K 30/88

(57) ABSTRACT

A first aspect of the present disclosure relates to a solar cell including, in a laminating direction, a transparent substrate, a first electrode layer containing a material that is transparent and conductive, a photoelectric conversion layer containing an organic-inorganic perovskite compound as a main component, a second electrode layer, and an antireflection layer containing nanoparticles having an average particle diameter of 100 nm or less, the antireflection layer being provided between the substrate and the first electrode layer.

### CROSS-REFERENCE TO RELATED APPLICATION

This application claims priority to Japanese Patent Application No. 2025-010434 filed on Jan. 24, 2025. The disclosure of the above-identified application, including the specification, drawings, and claims, is incorporated by reference herein in its entirety.

### BACKGROUND

### 1. Technical Field

A first aspect of the present disclosure relates to a solar cell.

### 2. Description of Related Art

As one type of a solar cell, there is known a perovskite-type solar cell in which a main component of a photoelectric conversion layer is a perovskite compound.

As the perovskite-type solar cell, for example, WO 2017/073472 discloses a perovskite solar cell including a transparent conductive support, an electron blocking layer, a perovskite layer, an electron transport layer, a hole blocking layer, and a back surface electrode. In the perovskite solar cell, both the electron blocking layer and the hole blocking layer contain an inorganic material.

### SUMMARY

There is a demand for a solar cell with high energy conversion efficiency, capable of efficiently converting incident sunlight into electricity.

A first aspect of the present disclosure provides a solar cell with high energy conversion efficiency.

The inventors have found that, in a solar cell, energy conversion efficiency of a solar cell to be obtained is improved by disposing nanoparticles between a substrate and a transparent electrode layer, and thus have completed the first aspect of the present disclosure.

The solar cell according to the first aspect of the present disclosure includes, in a laminating direction,
a transparent substrate,
a first electrode layer containing a material that is transparent and conductive,
a photoelectric conversion layer containing an organic-inorganic perovskite compound as a main component,
a second electrode layer, and
an antireflection layer containing nanoparticles having an average particle diameter of 100 nm or less, the antireflection layer being provided between the substrate and the first electrode layer.
   In the solar cell according to the first aspect of the present disclosure,
the substrate has flexibility, and the solar cell has a striped structure in which in a direction perpendicular to the laminating direction, a region where the antireflection layer is not provided and a region where the antireflection layer is provided appear alternately.
   In addition, in the solar cell according to the first aspect of the present disclosure, the substrate has a curvature, and a direction in which the striped structure of the antireflection layer appears is the same as a direction in which the curvature appears.

According to the first aspect of the present disclosure, it is possible to provide a solar cell with high energy conversion efficiency.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic cross-sectional view illustrating an example of a structure of the solar cell according to the first aspect of the present disclosure in a laminating direction;

FIG. 2 is a schematic view showing a perovskite-type crystal structure; and

FIG. 3 is a view schematically showing a configuration of the solar cell according to the first aspect of the present disclosure in a direction perpendicular to the laminating direction.

### DETAILED DESCRIPTION OF EMBODIMENTS

Hereinafter, preferred embodiments of one aspect of the present disclosure will be specifically described. In the present specification, features of the first aspect of the present disclosure will be described with reference to the drawings as appropriate. In the drawings, dimensions and shapes of each of parts are exaggerated for clarification, and actual dimensions and shapes are not accurately depicted. Therefore, the technical scope of the first aspect of the present disclosure is not limited to the dimensions and shapes of each of parts shown in the drawings. The solar cell according to the first aspect of the present disclosure are not limited to the following embodiments, and can be implemented in various forms in which changes, improvements, and the like appropriate for those skilled in the art are made without departing from the gist of the first aspect of the present disclosure.

The first aspect of the present disclosure relates to a solar cell including a photoelectric conversion layer that contains an organic-inorganic perovskite compound as a main component.

The solar cell according to the first aspect of the present disclosure includes, between a transparent substrate and a first electrode layer containing a material that is transparent and conductive, an antireflection layer containing nanoparticles having an average particle diameter of 100 nm or less.

Since the solar cell according to the first aspect of the present disclosure includes the antireflection layer containing the nanoparticles, it is possible to suppress reflection of incident sunlight at an interface of a substrate and an electrode layer, increase an amount of the sunlight incident on the photoelectric conversion layer, and as a result, improve energy conversion efficiency. That is, since the antireflection layer containing the nanoparticles is disposed, it is possible to reduce a reflectivity and improve power generation efficiency. In addition, since the antireflection layer is provided between the substrate and the first electrode layer, instead of a surface of the solar cell, it is possible to suppress a decrease in durability without being affected by dirt or friction on the surface.

### Configuration of Solar Cell in Laminating Direction

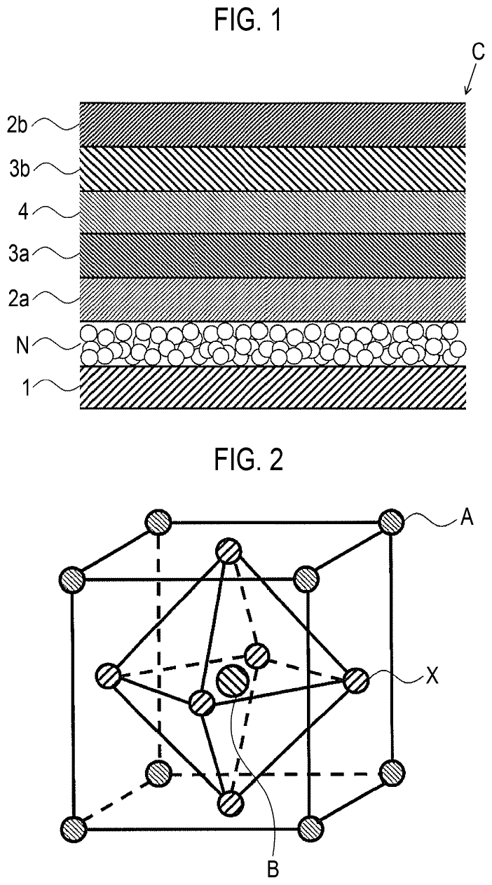

First, a structure of the solar cell according to the first aspect of the present disclosure will be described in detail. FIG. 1 is a schematic cross-sectional view illustrating an example of the structure of the solar cell according to the first aspect of the present disclosure in the laminating direction.

As shown in FIG. 1, in one embodiment, a solar cell C according to the first aspect of the present disclosure includes a substrate 1, an antireflection layer N, a first electrode layer 2a, a first carrier transport layer 3a, a photoelectric conversion layer 4, a second carrier transport layer 3b, and a second electrode layer 2b in this order.

### Antireflection Layer N

The antireflection layer N is a layer located at an intermediate portion of the substrate 1 and the first electrode layer 2a. The nanoparticles used for forming the antireflection layer N may be composed of the same material that is transparent and conductive as the material that is transparent and conductive, the material being used for forming the first electrode layer 2a, or may be composed of an insulating material such as glass. The antireflection layer N suppresses reflection of sunlight incident on the solar cell C at an interface of the substrate 1 and the first electrode layer 2a.

More specifically, the sunlight incident on the solar cell C is suppressed from being reflected toward the outside at the interface of the substrate 1 and the first electrode layer 2a by the antireflection layer N (that is, the reflection of the incident sunlight), and is likely to be transmitted toward the photoelectric conversion layer 4.

An average particle diameter of the nanoparticles in the antireflection layer N is 100 nm or less, in one embodiment 80 nm or less, in one embodiment 60 nm or less, in one embodiment 40 nm or less, and in one embodiment 20 nm or less. The lower limit value of the average particle diameter of the nanoparticles in the antireflection layer N is not limited. The average particle diameter of the nanoparticles in the antireflection layer N is usually 1 nm or more, in one embodiment 2 nm or more, in one embodiment 3 nm or more, in one embodiment 4 nm or more, and in one embodiment 5 nm or more. Here, the average particle diameter of the nanoparticles can be measured by a dynamic light scattering method (DLS). As the average particle diameter of the nanoparticles in the antireflection layer N decreases, formation of unevenness on a surface of the first electrode layer 2a is suppressed, and thus the reflection of sunlight at the interface can be further suppressed.

A film thickness of the antireflection layer N is usually in a range of 1 nm or more and 200 nm or less, and in one embodiment in a range of 20 nm or more and 100 nm or less.

### Photoelectric Conversion Layer 4

The description of FIG. 1 will be resumed. The photoelectric conversion layer 4 is a layer located at an intermediate portion of the first carrier transport layer 3a and the second carrier transport layer 3b. The photoelectric conversion layer 4 generates charge carriers by receiving light.

The charge carriers generated in the photoelectric conversion layer 4 move to any one of the first carrier transport layer 3a or the second carrier transport layer 3b.

More specifically, positive charge carriers, that is, holes generated in the photoelectric conversion layer 4 are transported to the first electrode layer 2a or the second electrode layer 2b through a layer corresponding to a hole transport layer among the first carrier transport layer 3a and the second carrier transport layer 3b.

In addition, negative charge carriers, that is, electrons generated in the photoelectric conversion layer 4 are transported to the first electrode layer 2a or the second electrode layer 2b through a layer corresponding to an electron transport layer among the first carrier transport layer 3a and the second carrier transport layer 3b.

The photoelectric conversion layer 4 contains an organic-inorganic perovskite compound, and in one embodiment, the photoelectric conversion layer 4 contains the organic-inorganic perovskite compound as a main component. A content of the organic-inorganic perovskite compound in the photoelectric conversion layer 4 is usually 60% by weight or more, in one embodiment 80% by weight or more, in one embodiment 90% by weight or more, in one embodiment 95% by weight or more, and in one embodiment 100% by weight.

A film thickness of the photoelectric conversion layer is usually in a range of 100 nm or more and 1,000 nm or less, and in one embodiment in a range of 400 nm or more and 700 nm or less.

The organic-inorganic perovskite compound is a compound having a perovskite-type crystal structure. FIG. 2 is a schematic view showing the perovskite-type crystal structure. As shown in FIG. 2, the perovskite-type crystal structure has a unit lattice of a cubic crystal system, in which A is disposed at each vertex of a cubic crystal, B is disposed at a body center, and X is disposed at a surface center of the cubic crystal with the body center as a center. The fact that the compound has the perovskite-type crystal structure can be confirmed by, for example, X-ray diffraction measurement.

The organic-inorganic perovskite compound can be represented by, for example, Formula (1)

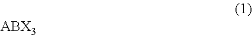

(in the formula, A is a monovalent cation and includes at least one organic cation, B is a divalent cation, and X is a monovalent anion).

In one embodiment, in Formula (1), A is at least one selected from a monovalent organic ammonium ion and a monovalent amidinium-based ion. Examples of the monovalent organic ammonium ion include CH₃NH₃⁺ (methylammonium ion; MA), C₂H₅NH₃⁺, C₃H₇NH₃⁺, and C₄H₉NH₃⁺.

Examples of the monovalent amidinium-based ion include HC(NH₂)₂⁺ (formamidinium ion; FA).

In one embodiment, in Formula (1), A may further include a monovalent metal ion. Examples of the monovalent metal ion include a rubidium ion (Rb⁺) and a cesium ion (Cs⁺).

In Formula (1), A may be a combination of the monovalent organic ammonium ion, the monovalent amidinium-based ion, and the monovalent metal ion. In one embodiment, in Formula (1), A is MA or FA, or a combination of two selected from the group consisting of MA, FA, and Cs⁺. In one embodiment, in Formula (1), A is a mixed cation of Cs⁺, MA, and FA. In a case where A is a mixed cation, a mixing ratio of each of cations is not limited.

In one embodiment, in Formula (1), B is a divalent metal ion, and is, for example, a lead ion (Pb²⁺), a tin ion (Sn²⁺), or a combination of these ions. In one embodiment, from the viewpoint of improving durability, B is Pb²⁺.

In one embodiment, in Formula (1), X is a halogen ion, and is, for example, at least one selected from a fluoride ion (F⁻), a chloride ion (Cl⁻), a bromide ion (Br⁻), and an iodide ion (I⁻). In one embodiment, in Formula (1), X is at least one selected from Cl⁻, Br⁻, and I⁻. In one embodiment, in Formula (1), X is I⁻.

### First Carrier Transport Layer 3a and Second Carrier Transport Layer 3b

The description of FIG. 1 will be resumed.

The first carrier transport layer 3a receives the charge carriers generated in the photoelectric conversion layer 4, and transports the charge carriers to the first electrode layer 2a.
In a case where the first carrier transport layer 3a is a hole transport layer (HTL), the first carrier transport layer 3a transports holes to the first electrode layer 2a.
In a case where the first carrier transport layer 3a is an electron transport layer (ETL), the first carrier transport layer 3a transports electrons to the first electrode layer 2a.
Detailed description of the hole transport layer and the electron transport layer will be described later.

The second carrier transport layer 3b receives the charge carriers generated in the photoelectric conversion layer 4, and transports the charge carriers to the second electrode layer 2b.

In a case where the second carrier transport layer 3b is a hole transport layer, the second carrier transport layer 3b transports holes to the second electrode layer 2b.
In a case where the second carrier transport layer 3b is an electron transport layer, the second carrier transport layer 3b transports electrons to the second electrode layer 2b.

In a first embodiment, the first carrier transport layer 3a is an electron transport layer and the second carrier transport layer 3b is a hole transport layer. That is, in the first embodiment, the solar cell C according to the first aspect of the present disclosure includes a substrate, an antireflection layer, a cathode, an electron transport layer, a photoelectric conversion layer, a hole transport layer, and an anode in this order.

Otherwise, in a second embodiment, the first carrier transport layer 3a is a hole transport layer and the second carrier transport layer 3b is an electron transport layer. That is, in the second embodiment, the solar cell C according to the first aspect of the present disclosure includes a substrate, an antireflection layer, an anode, a hole transport layer, a photoelectric conversion layer, an electron transport layer, and a cathode in this order.

The hole transport layer has a function of transporting the holes generated by photoelectric conversion in the photoelectric conversion layer to the first electrode layer or the second electrode layer. As a material of the hole transport layer, an organic material or an inorganic material, which is known to be usable in the hole transport layer, can be used.

The organic material that can be used as the material of the hole transport layer is not particularly limited, and examples thereof include 2,2′,7,7′-tetrakis-(N,N-di-4-methoxyphenylamino)-9,9′-spirobifluorene (Spiro-OMeTAD), polyethylene dioxythiophene:polystyrene sulfonate (PEDOT:PSS), poly[bis(4-phenyl)(2,4,6-trimethylphenyl)amine] (PTAA), and 3PATAT-C3 (non-patent document; Journal of The American Chemical Society 2023, Vol. 145, page 7528).

The inorganic material which can be used as the material of the hole transport layer is not particularly limited, and examples thereof include nickel oxide and copper oxide.

In one embodiment, in the above-described first embodiment of the solar cell according to the first aspect of the present disclosure, the material of the hole transport layer is one or more selected from the group consisting of Spiro-OMeTAD, PTAA, and nickel oxide.

In one embodiment, in the above-described second embodiment of the solar cell according to the first aspect of the present disclosure, the material of the hole transport layer is one or more selected from the group consisting of PEDOT:PSS, PTAA, and nickel oxide.

The electron transport layer has a function of transporting the electrons generated by photoelectric conversion in the photoelectric conversion layer to the first electrode layer or the second electrode layer. As a material of the electron transport layer, an organic material or an inorganic material, which is known to be usable in the electron transport layer, can be used.

The organic material that can be used as the material of the electron transport layer is not particularly limited, and examples thereof include a fullerene compound, a phenanthroline derivative (for example, bathocuproine), and polyethyleneimines. Examples of the fullerene compound include a fullerene (for example, C60 fullerene or C70 fullerene) and a derivative obtained by adding a substituent to the fullerene (for example, [6,6]-phenyl-C₆₁-butyric acid methyl ester (PCBM or also referred to as [60]PCBM) or [6,6]-phenyl-C₇₁-butyric acid methyl ester (PCBM or also referred to as [70]PCBM)).

Examples of the inorganic material that can be used as the material of the electron transport layer include titanium oxide, tin oxide, and zinc oxide.

In one embodiment, in the above-described first embodiment of the solar cell according to the first aspect of the present disclosure, the material of the electron transport layer is one or more selected from the group consisting of the fullerene, PCBM, bathocuproine, polyethyleneimines, titanium oxide, and tin oxide.

In one embodiment, in the above-described second embodiment of the solar cell according to the first aspect of the present disclosure, the material of the electron transport layer is one or more selected from the group consisting of the fullerene, PCBM, bathocuproine, and polyethyleneimines.

### First Electrode Layer 2a and Second Electrode Layer 2b

The first electrode layer 2a is an electrode in contact with the first carrier transport layer 3a. In a case where the first carrier transport layer 3a is a hole transport layer, the first electrode layer 2a is an anode; and in a case where the first carrier transport layer 3a is an electron transport layer, the first electrode layer 2a is a cathode. In addition, the second electrode layer 2b is an electrode in contact with the second carrier transport layer 3b. In a case where the second carrier transport layer 3b is a hole transport layer, the second electrode layer 2b is an anode; and in a case where the second carrier transport layer 3b is an electron transport layer, the second electrode layer 2b is a cathode.

The first electrode layer 2a is a transparent electrode layer, and as a material of the transparent electrode layer, a transparent conductive film, such as indium tin oxide (ITO), indium zinc oxide (IZO), aluminum-doped zinc oxide (AZO), and fluorine-doped tin oxide (FTO), can be used.

As a material of the second electrode layer 2b, a known material used as an electrode for a solar cell, including a metal material such as aluminum (Al), silver (Ag), and gold (Au), a transparent conductive film such as ITO, IZO, AZO, and FTO, and carbon nanotubes, can be used.

In one embodiment, the materials of the first electrode layer 2a and the second electrode layer 2b are ITO, IZO, and FTO.

In one embodiment, film thicknesses of the first electrode layer 2a and the second electrode layer 2b are usually in a range of 100 nm or more and 300 nm or less.

### Substrate 1

The substrate 1 is a plate-shaped or film-shaped member, and supports the antireflection layer N, the first electrode layer 2a, the first carrier transport layer 3a, the photoelectric conversion layer 4, the second carrier transport layer 3b, and the second electrode layer 2b.

The substrate 1 is a transparent substrate. As the transparent substrate, a substrate contains one or more materials selected from an inorganic material such as glass, and an organic material such as polyethylene, polyethylene terephthalate, polyethylene naphthalate, polyimide, polyamide, polyamideimide, a liquid crystal polymer, and a cycloolefin polymer can be used.

In one embodiment, the substrate 1 contains a material having flexibility. Here, the “flexibility” means a property of being gently bent by an external force, that is, means a property of being flexible and difficult to break even in a case of being bent. With the substrate 1 having flexibility, the solar cell can be installed on a curved surface in a case of being mounted in a vehicle; and with the antireflection layer having a striped structure as described later, cracks that may occur in a case of being bent can be reduced.

### Configuration of Solar Cell in Direction Perpendicular to Laminating Direction

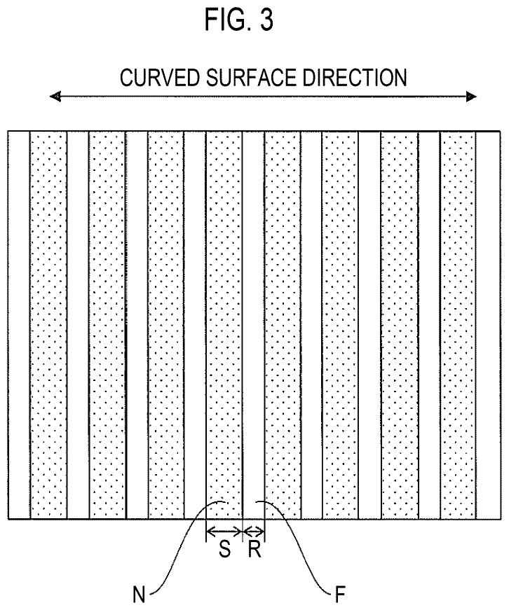

FIG. 3 schematically shows a configuration of the solar cell C according to the first aspect of the present disclosure in a direction perpendicular to the laminating direction. The solar cell according to the first aspect of the present disclosure has a striped (patterned) structure in which a region (width R) where the antireflection layer N is not formed and a region (width S) where the antireflection layer N is formed appear alternately in the direction perpendicular to the laminating direction. A film F is provided in the region where the antireflection layer N is not formed.

In the solar cell C according to the first aspect of the present disclosure, the substrate has a curvature, and in the direction perpendicular to the laminating direction, a direction in which the striped structure of the antireflection layer N appears is the same as a direction in which the curvature appears. Therefore, in the solar cell C according to the first aspect of the present disclosure, the direction perpendicular to the laminating direction is also referred to as a curved surface direction.

In a case where the solar cell C according to the first aspect of the present disclosure having such a structure is used as, for example, an in-vehicle panel solar cell of being mounted on a roof of an automobile, occurrence of cracks in the antireflection layer N due to use on a curved surface can be prevented.

In one embodiment, a ratio (R/S) of the width R to the width S in the striped structure formed depending on the presence or absence of the antireflection layer N is not particularly limited, but is usually in a range of 0.01 or more and 1 or less, and in one embodiment in a range of 0.1 or more and 0.5 or less.

In a case where the ratio of the width R to the width S is within the above-described range, in the solar cell C, the occurrence of cracks in the antireflection layer N due to use on a curved surface can be prevented while ensuring an effect of suppressing the reflection of sunlight by the antireflection layer N.

The solar cell according to the first aspect of the present disclosure can be used alone, or in combination with other solar cells such as a silicon (Si) solar cell. In a case of being used in combination with other solar cells, for example, the solar cell according to the first aspect of the present disclosure can be a tandem-type solar cell in which other solar cells are laminated on a side of the second electrode layer (counter electrode of the substrate) in the solar cell according to the first aspect of the present disclosure.

### Method for Manufacturing Solar Cell

Next, a method for manufacturing a solar cell, that is, a manufacturing method

according to the first aspect of the present disclosure will be described in more detail.

In the manufacturing method according to the present embodiment, the solar cell is manufactured by forming, on the substrate 1, the antireflection layer N, the first electrode layer 2a, the first carrier transport layer 3a, the photoelectric conversion layer 4, the second carrier transport layer 3b, and the second electrode layer 2b in this order. The manufacturing method according to the present embodiment is characterized in that, on a surface where the substrate 1 and the transparent electrode layer as the first electrode layer 2a are in contact with each other, using the region where the antireflection layer N is not formed as a mask, a dispersion liquid containing nanoparticles is applied only onto the region where the antireflection layer N is formed to form the antireflection layer N; and a film forming step of the other portions can adopt the same method as that of a photoelectric conversion element (solar cell) in the related art. Examples of another manufacturing method according to the present embodiment include a coating method that can perform pattern coating, such as ink jet, and a method of removing only a target region by laser scribbling or the like after forming a layer by coating.

The dispersion liquid containing the nanoparticles can be applied onto the substrate 1 by a known method. The method of applying the dispersion liquid containing the nanoparticles is not particularly limited, and examples thereof include a spin coating method, an ink jet method, a spray method, a blade coating method, and a die coating method.

The application of the dispersion liquid containing the nanoparticles can be usually performed in a range of 15° C. or higher and 35° C. or lower in the atmosphere.

As the nanoparticles, ITO, IZO, AZO, FTO, or the like, which is a material that is transparent and conductive, or glass or the like, which is an insulating material, can be used. In one embodiment, an average particle diameter of the nanoparticles is 100 nm or less, in one embodiment 80 nm or less, in one embodiment 60 nm or less, in one embodiment 40 nm or less, and in one embodiment 20 nm or less. The lower limit value of the average particle diameter of the nanoparticles is not limited. The average particle diameter of the nanoparticles is usually 1 nm or more, in one embodiment 2 nm or more, in one embodiment 3 nm or more, in one embodiment 4 nm or more, and in one embodiment 5 nm or more. Here, the average particle diameter of the nanoparticles can be measured by a dynamic light scattering method (DLS). As the average particle diameter of the nanoparticles decreases, formation of unevenness on a surface of the first electrode layer is suppressed, and thus the reflection of sunlight at the interface can be further suppressed.

A concentration of the nanoparticles in the dispersion liquid containing the

nanoparticles is not particularly limited, but is usually 5% by weight or less and in one embodiment 3% by weight or less with respect to the total weight of the dispersion liquid. By setting the concentration of the nanoparticles to the above-described concentration, the reflection of incident sunlight can be suppressed, and thus the transmission of the sunlight to the photoelectric conversion layer in the solar cell and the absorption of the sunlight by the photoelectric conversion layer can be improved.

A solvent of the dispersion liquid containing the nanoparticles is an alcohol, for example, isopropyl alcohol (iPA). By using an alcohol as the solvent of the dispersion liquid containing the nanoparticles, deterioration of the photoelectric conversion layer or the carrier transport layer can be suppressed.

The manufacturing method according to the first aspect of the present disclosure can include a step of drying the applied dispersion liquid containing the nanoparticles. The drying step can be usually performed by heating in a range of 80° C. or higher and 150° C. or lower.

In the manufacturing method according to the first aspect of the present disclosure, layers other than the antireflection layer can be formed by a known film forming method. In one embodiment, ITO used in the electrode layer of the first electrode layer and the like can be formed by sputtering.

What is claimed is:

1. A solar cell comprising, in a laminating direction:
a transparent substrate;
a first electrode layer containing a material that is transparent and conductive;
a photoelectric conversion layer containing an organic-inorganic perovskite compound as a main component;
a second electrode layer; and
an antireflection layer containing nanoparticles having an average particle diameter of 100 nm or less, the antireflection layer being provided between the substrate and the first electrode layer.

2. The solar cell according to claim 1,
wherein the substrate has flexibility, and
wherein, the solar cell has a striped structure in which in a direction perpendicular to the laminating direction, a region where the antireflection layer is not provided and a region where the antireflection layer is provided appear alternately.

3. The solar cell according to claim 2,
wherein the substrate has a curvature, and
wherein a direction in which the striped structure of the antireflection layer appears is the same as a direction in which the curvature appears.
